(19) United States
(12) Patent Application Publication
(10) Pub. No.: US 2013/0177717 A1
(43) Pub. Date: Jul. 11, 2013

(54) METHOD FOR PRODUCING WAVELENGTH PLATE

(71) Applicants: Nobuyuki Koike, Miyagi (JP); Takatoshi Yamada, Miyagi (JP); Akio Takada, Miyagi (JP); Masatoshi Sasaki, Miyagi (JP)

(72) Inventors: Nobuyuki Koike, Miyagi (JP); Takatoshi Yamada, Miyagi (JP); Akio Takada, Miyagi (JP); Masatoshi Sasaki, Miyagi (JP)

(73) Assignee: DEXERIALS CORPORATION, Tokyo (JP)

(21) Appl. No.: 13/806,960

(22) PCT Filed: Jun. 23, 2011
(86) PCT No.: PCT/JP2011/064394

§ 371 Date: Feb. 7, 2013

(30) Foreign Application Priority Data
Jun. 25, 2010 (JP) 2010-144559

(51) Int. Cl. C23C 16/40

(52) U.S. Cl. CPC C23C 16/40
USPC 427/569; 427/162; 427/255.7

(57) ABSTRACT

To produce a wavelength plate that is superior in durability and stability and has a high moisture resistant property. A dielectric material is obliquely vapor deposited on a substrate so as to form a birefringent layer that has columnar portions in each of which fine particles of the dielectric material are stacked in a columnar shape, and interstices that are respectively formed between the columnar portions, and the birefringent layer is subjected to an annealing treatment at a temperature within the range of 100° C. or more to 300° C. or less. Then, a protective film with low moisture permeability is formed on the annealed birefringent layer by forming an inorganic compound on the birefringent layer at high density.

### FIELD OF THE INVENTION

This invention relates to a wavelength plate having a birefringence rate derived from a birefringent layer formed by oblique vapor deposition. The present application asserts priority rights based on JP Patent Application 2010-144559 filed in Japan on Jun. 25, 2010. The total contents of disclosure of the patent application of the senior filing date are to be incorporated by reference into the present application.

### BACKGROUND OF THE INVENTION

Conventionally, a wavelength plate is manufactured by using an inorganic optical single crystal, such as quartz or the like, and a polymeric oriented film in most cases. However, although the inorganic optical single crystal is superior in performances, durability and reliability for use as a wavelength plate, its material cost and processing cost are high. Moreover, the polymeric oriented film tends to easily deteriorate upon application of heat and UV light rays thereto, and has a problem in its durability.

Therefore, as described in Patent Literatures 1 to 4, an optical element has been proposed in which grains are vapor deposited on a substrate surface in an oblique direction to form an oblique columnar structure and which is thus allowed to exert a birefringence property relative to light rays that are made incident on the substrate surface. On principle, this oblique vapor deposition wavelength plate with the obliquely vapor deposited film having the oblique columnar structure formed thereon makes it possible to set a desired phase difference by adjusting the film thickness. Moreover, the plate can be relatively easily formed into a large area and consequently reduce costs through mass production.

Patent Literature 1 has described an obliquely vapor deposited film that is composed of at least two layers formed by obliquely vapor depositing a material that exerts high frequency dispersion and a material that exerts low frequency dispersion in their phase differences, and is applicable to a wavelength plate in a wide band of visible light rays. The obliquely vapor deposited film of this Patent Literature 1 has a structure in which the material that exerts high frequency dispersion and the material that exerts low frequency dispersion are respectively used so that the respective layers are stacked, with the vapor depositing directions of the dielectric materials of the respective layers being different from each other, in a manner so as to make lag axes of the vapor deposition films orthogonal to each other.

Moreover, Patent Literature 2 has described an optical retarder that is provided with a birefringent layer with a densely integrated structure formed by oblique vapor deposition so that high durability and high stability are achieved. Furthermore, Patent Literature 3 has described a hologram polarizing element for use in optical pickup, which is produced by obliquely vapor depositing a high refractive index material on a one dimensional lattice. Patent Literature 4 has also described a photonic crystal type wavelength plate that is adapted to set a wide operational wavelength by using an alternate multilayer film of high refractive index layers and low refractive index layers having a periodic concave/convex shape.

### PRIOR-ART DOCUMENTS

### Patent Documents

PTL 1: Japanese Patent Application Laid-Open No. 11-23840
PTL 2: Japanese Patent Application Laid-Open No. 2007-188060
PTL 3: Japanese Patent Application Laid-Open No. 11-250483
PTL 4: WO No. 2004/113974

### SUMMARY OF THE INVENTION

With respect to the wavelength plate on which such an obliquely vapor deposited film is formed, a high moisture resistant property is required so as to obtain high durability and high stability. However, since the wavelength plate with the obliquely vapor deposited film formed thereon has a columnar structure, moisture easily enters between gaps of the materials, resulting in a problem of degradation in the moisture resistant property.

The present invention has been devised in view of the above-mentioned circumstances, and relates to a wavelength plate having a birefringence rate derived from a birefringent layer formed by oblique vapor deposition, and its object is to provide a method for producing a wavelength plate that has a high moisture resistant property and exerts superior durability and stability.

The present inventors have intensively carried out various researches and have found that by forming a protective film with a low moisture permeating property on fine grains that are vapor deposited on a substrate through an oblique vapor deposition process, a wavelength plate that has a high moisture resistant property and exerts superior durability and stability can be produced.

That is, a method for producing a wavelength plate in accordance with the present invention is characterized by including: a step of obliquely vapor depositing a dielectric material on a substrate to form a birefringent layer having columnar portions formed by stacking fine grains of the dielectric material in a columnar shape and interstices formed between the columnar portions; annealing the birefringent layer at a temperature in a range from 100° C. or more to 300° C. or less; and by forming an inorganic compound at high density on the birefringent layer that has been subjected to the annealing treatment, forming a protective film thereon.

### EFFECTS OF INVENTION

In accordance with the method of producing a wavelength plate of the present invention, it is possible to produce a wavelength plate that has a high moisture resistant property and exerts superior durability and stability.

### BRIEF DESCRIPTION OF DRAWINGS

FIG. 1 is a drawing for explaining a shape anisotropy of fine grains of a dielectric material.

FIG. 2 is a schematic cross-sectional view that shows a wavelength plate in accordance with one embodiment of the present invention.

FIG. 3 is a schematic cross-sectional view that shows a wavelength plate in accordance with another embodiment of the present invention.

FIG. 4A is a view showing a structural example of a substrate, and FIG. 4B is a view showing another structural example of a substrate.

FIG. 5 is a schematic cross-sectional view that shows a wavelength plate in accordance with one embodiment of the present invention.

FIG. 6 is a schematic cross-sectional view that shows a wavelength plate in accordance with another embodiment of the present invention.

FIG. 7 is a cross-sectional view that shows an essential portion of a wavelength plate in accordance with the embodiment of the present invention.

FIG. 8 is a flow chart that indicates a method for producing the wavelength plate in accordance with the embodiment of the present invention.

FIG. 9 is a view for explaining the outline of oblique vapor deposition.

FIG. 10 is a view that indicates a transmittance immediately after completion of a sample of a wavelength plate in example 1 and a transmittance obtained after the sample has been held for 100 hours in a moisture resistant load test therein.

FIG. 11 is a view that indicates a transmittance of a wavelength plate in which the anneal temperature is changed.

FIG. 12 is a view that indicates a transmittance immediately after completion of a sample of a wavelength plate in comparative example 1 and a transmittance obtained after the sample has been held for 100 hours in a moisture resistant load test in example 1.

FIG. 13 is a view that indicates a transmittance immediately after completion of a sample of a wavelength plate in comparative example 2 and a transmittance obtained after the sample has been held for 100 hours in a moisture resistant load test therein.

FIG. 14 is a view that shows comparison of birefringence quantities between a wavelength plate using a one dimensional lattice substrate and a wavelength plate using a flat substrate.

FIG. 15 is a view that shows an SEM image of a cross section of the wavelength plate using the one dimensional lattice substrate.

### DETAILED DESCRIPTION OF THE INVENTION

Referring to Figures, the following description will discuss an embodiment of the present invention (hereinafter, referred to as “present embodiment”) in the following order in detail:

1. Method for Producing Wavelength plate

### 2. Modified Examples

### 2-1. Modified Example 1

### 2-2. Modified Example 2

### 2-3. Modified Example 3

### 3. Treatment Process

### 4. Examples

### 1. METHOD FOR PRODUCING WAVELENGTH PLATE

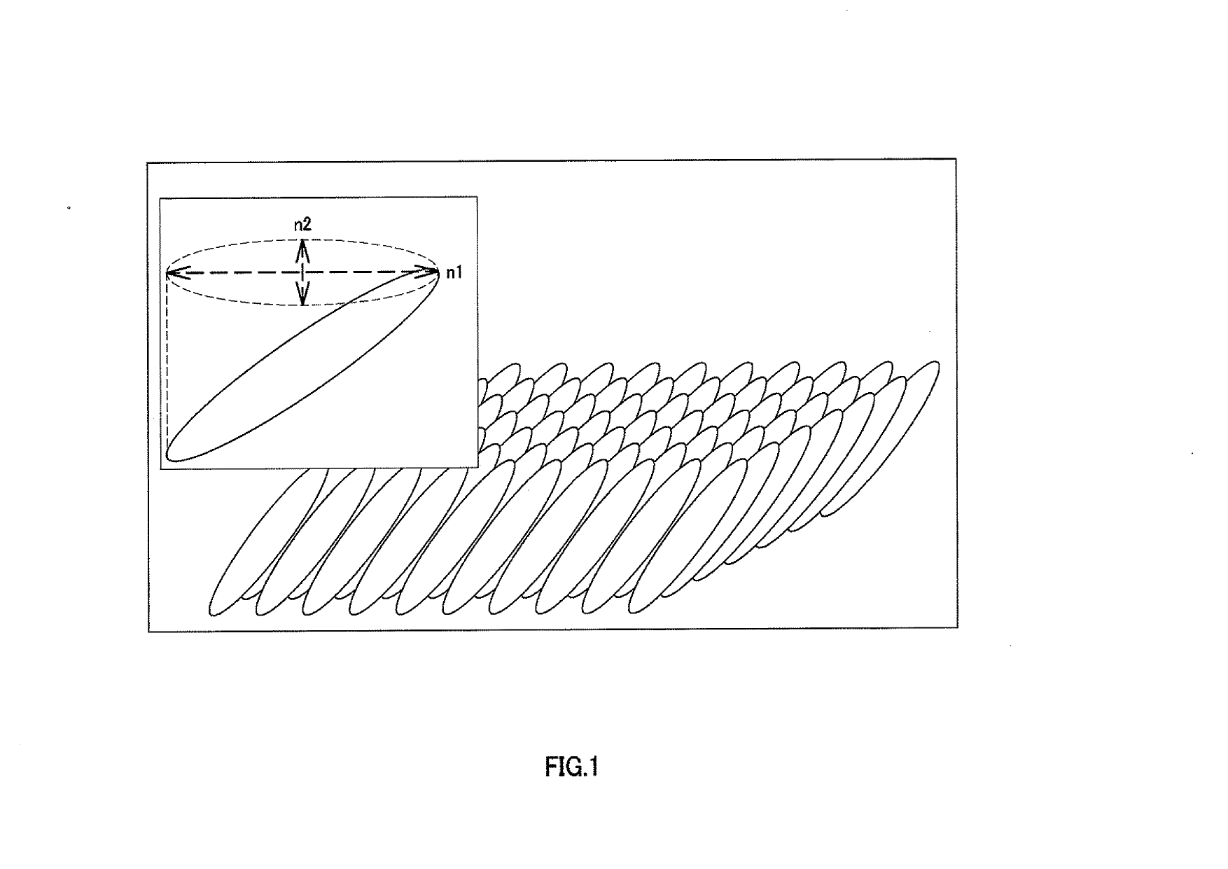

A method for producing a wavelength plate in accordance with the present embodiment, which produces a wavelength plate that can increase the birefringence quantity by utilizing the birefringence of fine grains derived from oblique vapor deposition, and in this method, after a birefringent layer (obliquely vapor deposited film) has been formed by obliquely vapor depositing a dielectric material on a transparent substrate, moisture inside the birefringent layer is evaporated by an annealing treatment, and thereafter, by forming an inorganic compound on the birefringent layer at high density, a protective film having a low moisture permeating property is formed thereon. For example, as shown in FIG. 1, the birefringence of fine grains derived from this oblique vapor deposition is exerted by the fact that a difference in refractive indexes between a major-axis direction n1 and a minor-axis direction n2 is generated by shape anisotropy of fine grains of the dielectric material.

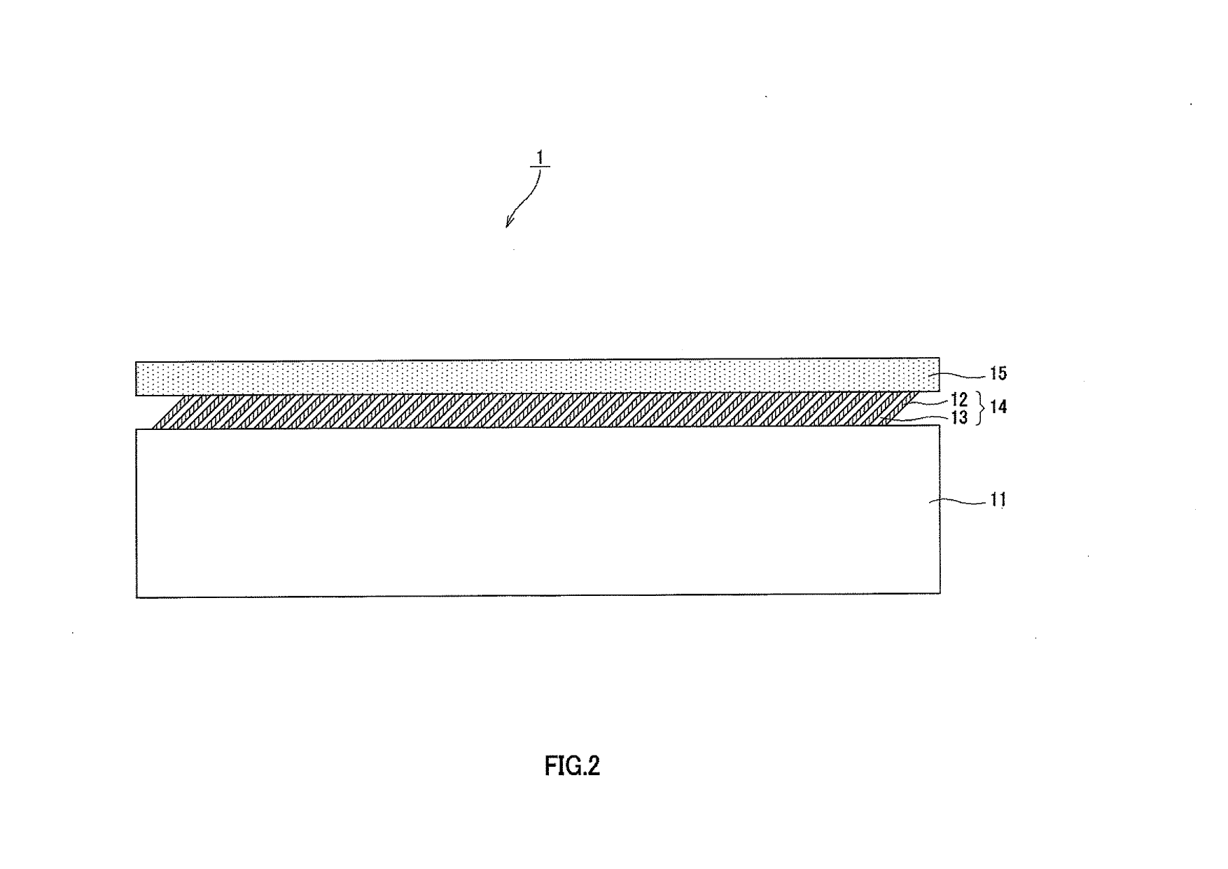

In the method for manufacturing a wavelength plate in the present embodiment, for example, a wavelength plate, as shown in a cross-sectional view of FIG. 2, is manufactured. In the wavelength plate shown in FIG. 2, columnar portions 12 are formed on a substrate 11 by obliquely vapor depositing a dielectric material thereon in one direction. Thus, interstices 13 are formed between the plural columnar portions 12. This birefringent layer 14 composed of the columnar portions 12 and interstices 13 is subjected to an annealing treatment so that moisture inside the interstices 13 is evaporated. Thereafter, an organic compound is formed on the birefringent layer 14 at high density so that a protective film 15 is formed.

As the substrate 11, a transparent substrate, such as a glass substrate, a silicon substrate, a plastic substrate, or the like, is used. Among these, a quartz glass (SiO₂) substrate having less absorption in a visible light area (wavelength range: 380 nm to 780 nm) is more preferable.

As the substrate, a transparent substrate, such as a glass substrate, a silicon substrate, a plastic substrate, or the like, is used, and among these, a quartz glass (SiO₂) substrate having less absorption in a visible light area (wavelength range: 380 nm to 780 nm) is more preferably used. Moreover, a substrate on one surface of which an anti-reflection film is formed may be used. In this case, as the anti-reflection film, for example, a general-use multilayer thin film made of a high refractive-index film and a low refractive-index film may be formed.

The columnar portions 12 are formed by stacking fine grains by oblique vapor depositing processes of the dielectric material. As the dielectric material, a high refractive-index material containing, Ta₂O₅, TiO₂, SiO₂, Al₂O₃, Nb₂O₅, MaF₂ or the like, is used, and among these, a high refractive-index material containing Ta₂O₅ and having a refractive index of 2.25 is preferably used.

Supposing that the xy plane of x, y and z orthogonal coordinates forms a substrate surface, the columnar portions 12 are formed by obliquely vapor depositing the dielectric material onto the xy plane. This oblique vapor depositing process is carried out with a vapor depositing angle of, for example, in a range from 60° to 80° relative to the z-axis, so that layers of fine grains are formed in the z-axis direction.

Each of the interstices 13 is an air layer formed between the columnar portions 12. The interstices 13 are formed by a so-called self-shadowing effect in which, since the fine grains of the dielectric material come flying in oblique directions, a shadow portion is formed to which the dielectric material is not allowed to directly adhere. In the conventional wavelength plate on which a birefringent layer is formed by an oblique vapor depositing process, since the interstices 13 are air layers formed in oblique directions, moisture inside the interstices 13, for example, moisture or the like adhered to the side faces of the columnar portions 12, is hardly evaporated toward the outside of the birefringent layer 14 to cause a problem of a low moisture resistance.

Therefore, in the present embodiment, by carrying out an annealing treatment on the birefringent layer 14 to evaporate moisture located inside the interstices 13, and a protective film 15 having a low moisture permeating property is formed on the birefringent layer 14. Thus, a wavelength plate having superior resistance to the outside moisture is achieved.

The annealing treatment is preferably carried out at a temperature of 100° C. or more that evaporates moisture. In the case when the temperature of the annealing treatment is too high, the columnar structures are mutually grown to form a columnar shape, with the result that a reduction in birefringence quantity and a reduction in transmittance might be caused; therefore, the temperature thereof is preferably set to 300° C. or less.

As the material for the protective film 15, for example, inorganic compounds, such as SiO₂, Ta₂O₅, TiO₂, Al₂O₃, Nb₂O₅, LaO, MaF₂ or the like, having a low moisture permeating property, are preferably used. Additionally, since polymer materials are poor in heat resistance, they are not desirable as materials for the protective film 15.

As the film-forming method for the protective film 15, any method that is capable of forming a protective film having a low moisture permeating property by forming such an inorganic compound at high density, is adopted. As such a film-forming method for the protective film 15, for example, a chemical vapor deposition (CVD) method is proposed. In the case of forming the protective film 15 by using the CVD method, a substrate on which a birefringent layer 14 has been formed is disposed in a container having the atmospheric pressure to middle vacuum pressure (100 to 10⁻¹ Pa), and a gaseous inorganic compound serving as a material for the protective film 15 is sent to this container, and by applying an energy, such as heat, plasma, light, or the like, thereto so that the gaseous inorganic compound and the birefringent layer 14 are chemically reacted with each other. In accordance with this CVD method, the inorganic compound is formed on the birefringent layer 14 at high density to provide a protective film 15 having a low moisture permeating property.

With respect to the film forming method of the protective film 15, in place of this CVD method, for example, any of methods that can form an organic compound at high density thereon, such as a plasma assist vapor deposition method, a sputtering method, etc., may be used.

The wavelength plate 1 thus produced has its birefringence quantity increased by fine grains vapor-deposited on the substrate 11 through the oblique vapor deposition, and since the protective film 15 having a low moisture permeating property is formed on the fine grains, it is possible to realize a high moisture resistant property together with superior durability and stability.

### 2. MODIFIED EXAMPLES

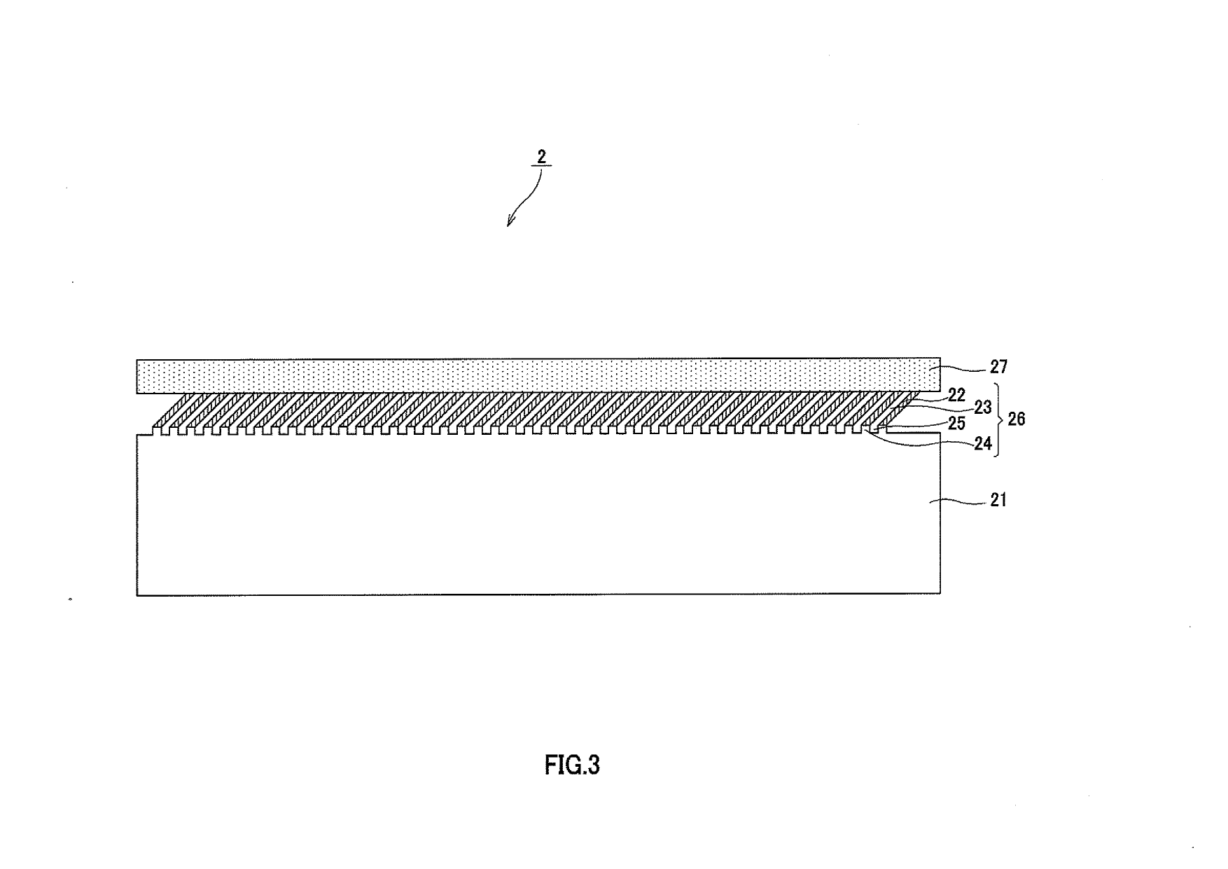

In the present embodiment, in place of the structure shown in FIG. 2, wavelength plates having structures, for example, shown in FIGS. 3, 5 and 6 may be produced. In the structures shown in FIGS. 3, 5 and 6, with respect to those structures that are the same as those shown in FIG. 2, the explanation thereof will be omitted.

### 2-1. Modified Example 1

A wavelength plate 2 shown in FIG. 3 is designed to increase the birefringence quantity by utilizing a birefringence of fine grains derived from oblique vapor deposition as well as by utilizing a birefringence derived from a fine structure. This birefringence derived from the fine structure corresponds to a birefringence that is exerted by, for example, shape anisotropy of a fine pattern composed of periodic concave and convex portions formed on a dielectric substrate.

Upon producing the wavelength plate 2, a fine pattern composed of periodic convex portions 24 and concave portions 25 having a period of not more than a wavelength of light to be used is formed on a substrate 21. Moreover, fine grains of a dielectric material are stacked with a columnar shape on the convex portions 24 by an oblique vapor depositing process of the dielectric material in one direction so that columnar portions 22 are formed. Thus, interstices 23 are formed on the concave portions 25, that is, between the columnar portions 22. Then, an annealing treatment is carried out on the birefringent layer 26 composed of the columnar portions 22 and the interstices 23 under the aforementioned conditions so that moisture that exists inside of each interstice 23 is evaporated. Thereafter, by forming an inorganic compound on the birefringent layer 26 by a CVD method or the like at high density, a protective film 27 having a low moisture permeating property is formed thereon.

In this manner, by the use of the wavelength plate 2 in which the columnar portions 22 are formed on the convex portions 24 of the substrate 21, with the interstices 23 being formed on the concave portions 25 of the substrate 2, it is possible to further increase the birefringence quantity by utilizing a birefringence derived from the fine grains of the dielectric material and a birefringence derived from the concave/convex structure of the substrate 21. Moreover, by using a high refractive index-material containing Ta₂O₅ as its dielectric material, it is possible to obtain a wavelength plate having a birefringence quantity of 0.13 or more in a visible light area.

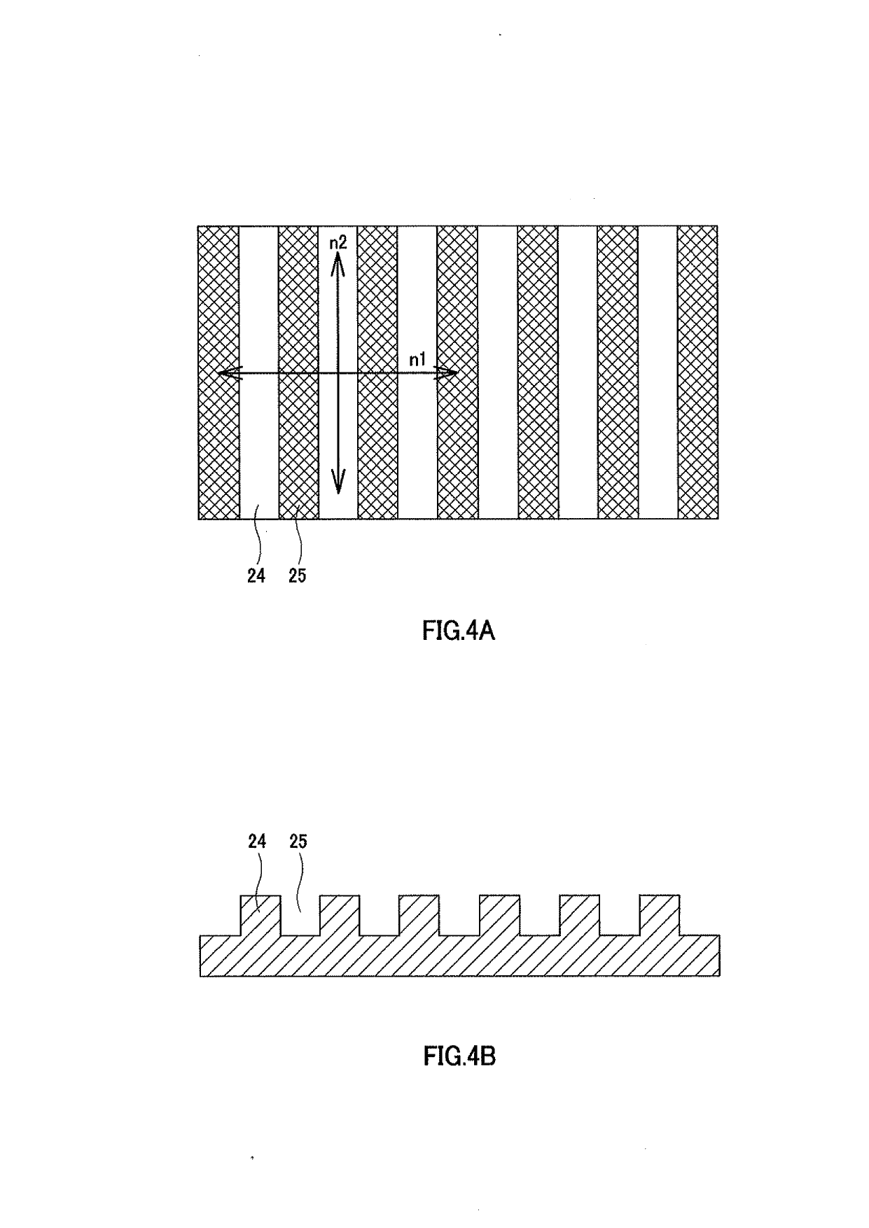

FIGS. 4A and 4B are a top view and a cross-sectional view respectively showing a structural example of the substrate 21. On the substrate 21, a pattern is formed in which supposing that an xy plane on x, y and z orthogonal coordinates is a substrate surface, convex portions 24 and concave portions 25 are formed as patterns thereon in the x-axis direction, with periods (pitches) each being not more than a wavelength of light to be used and a predetermined depth. That is, on the substrate 21, a one-dimensional lattice (grid), which generates a difference in refractive indexes between a major-axis direction n1 and a minor-axis direction n2 due to a path difference of the concave/convex structure, is formed.

Onto the convex portions 24 forming the fine pattern with pitches each being not more than the wavelength, a dielectric material is vapor deposited by carrying out an oblique vapor depositing process with its vapor deposition source being made perpendicular to the lattice lines, with a predetermined angle being made relative to the normal direction to the substrate surface. With this arrangement, in comparison with a vapor deposition process in which the dielectric material is vapor deposited directly on a flat substrate (hereinafter, referred to also as “flat substrate”) without any fine pattern formed thereon, the birefringence quantity of the wavelength plate can be increased.

In this manner, by combining the fine pattern and the birefringent film formed by the oblique vapor deposition with each other, the birefringence quantity is increased so that it is possible to provide a wavelength plate formed as a thin film capable of increasing the birefringence quantity to thereby achieve a desired phase characteristic. The thinness of the film provides various advantages, such as high speed and highly efficient production processes, reduced costs for materials to be used for the film formation, etc. The reason for the increased birefringence quantity obtained by forming the birefringent film on the fine pattern in this manner is considered to be derived from the fact that by producing interstices between the one dimensional lattices, the effects of a structural birefringence are further added thereto.

Additionally, as the method for forming the fine pattern, any method may be used as long as a fine pattern with pitches, each having a length of a wavelength or less, can be formed, and in addition to the above-mentioned one dimensional lattice, a random pattern, a pattern forming method in which a block copolymer is used, as described in Non-Patent Literature 1 (Toshiba Review vol. 60, No. 10, 2005), etc. may be listed. In the pattern forming method of Non-Patent Literature 1, an SiO₂ film is formed on a glass substrate by using, for example, a CVD method, a pattern is formed by using a block copolymer, and the pattern of the block copolymer is transferred onto the SiO₂ film.

Additionally, without forming the SiO₂ film on the glass substrate, a fine pattern may be directly formed thereon. In the case of a wavelength plate with the fine pattern is formed in this manner as well, by forming a protective film having a low moisture permeating property on the vapor deposition film, it is possible to provide a wavelength plate that has a high moisture resistance and is superior in stability.

### 2-2. Modified Example 2

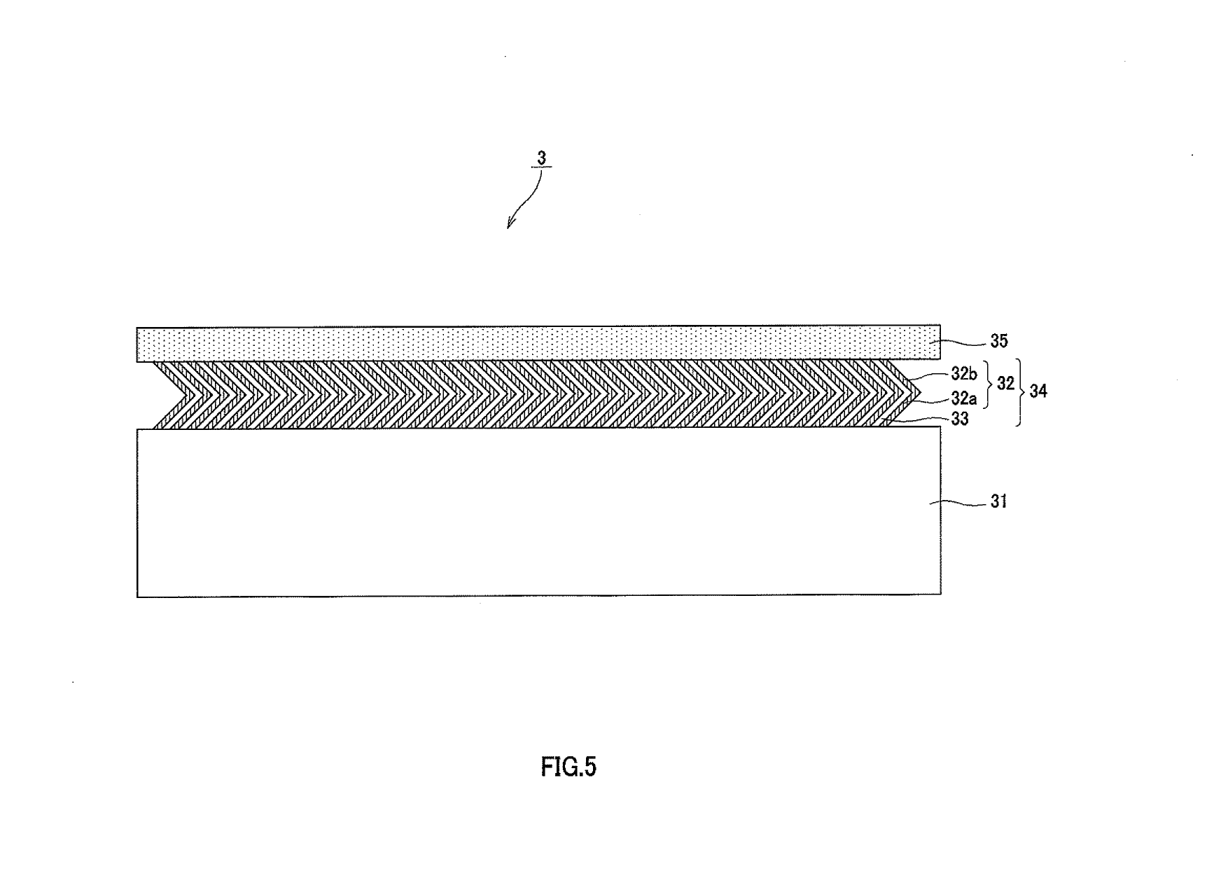

A wavelength plate 3 shown in FIG. 5 is designed to increase the birefringence quantity by utilizing a birefringence of fine grains formed by an oblique vapor depositing process carried out in two different directions. In the production of the wavelength plate 3, by stacking fine grains of a dielectric material on a substrate 31 by the oblique vapor depositing process in two different directions, columnar portions 32 composed of fine grain layers 32a and 32b are formed. Thus, interstices 33 are formed between the columnar portions 32. Then, an annealing treatment is carried out on the birefringent layer 34 composed of the columnar portions 32 and the interstices 33 under the aforementioned conditions so that moisture located inside the interstices 33 is evaporated. Thereafter, by forming an inorganic compound on the birefringent layer 34 at high density by using a CVD method or the like, a protective film 35 having a low moisture permeating property is formed thereon.

The columnar portions 32 are formed by obliquely vapor depositing the dielectric material successively in two directions different from each other by 180° on the xy plane, supposing that the xy plane on x, y and z orthogonal coordinates is a substrate surface. That is, the columnar portions 32 are formed by successively stacking the fine grain layers 32a and 32b on the substrate 31. These oblique vapor depositing processes are carried out successively from two directions different from each other by 180°, for example, with a vapor deposition angle of 60° to 80° relative to the z-axis, so that layers of fine grains are formed in the z-axis direction. In this case, it is supposed that operations in which, after an oblique vapor depositing process has been carried out from one direction, another oblique vapor depositing process is carried out from the other direction by rotating the substrate 31 by 180° are prepared as one cycle. By carrying out this cycle a plurality of times, a multilayer film subjected to the vapor deposition processes from two directions is obtained.

The thickness of each of the layers (fine grain layers 32a and 32b) of the columnar portions 32 is preferably set to 50 nm or less, more preferably, 10 nm or less. By making the thickness of each of the fine grain layers 32a and 32b thinner in this manner, it is possible to obtain a columnar shape that is extended straightly in the z-axis direction even in the case when the number of the fine grain layers is further increased, thereby making it possible to further increase the birefringence quantity.

### 2-3. Modified Example 3

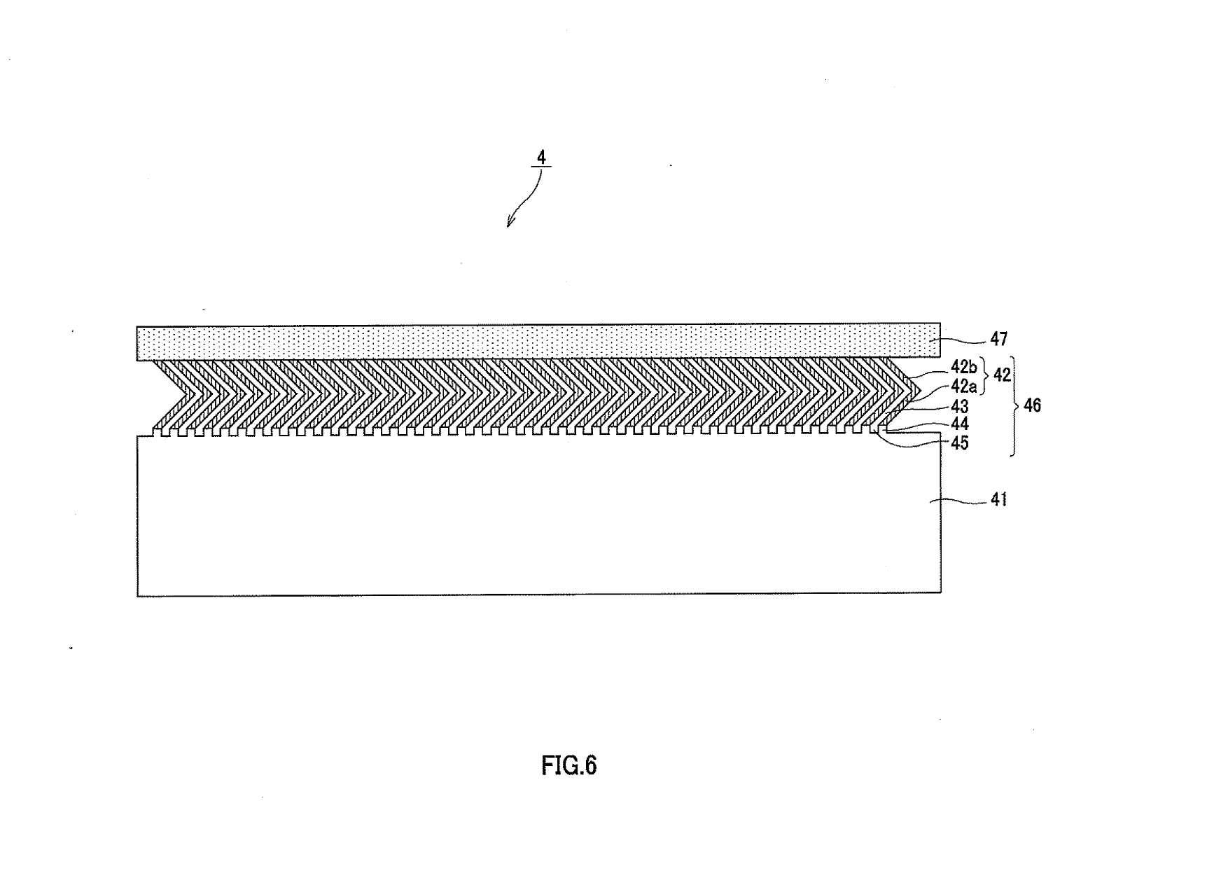

A wavelength plate 4 shown in FIG. 6 is designed to increase the birefringence quantity by utilizing a birefringence of fine grains formed by an oblique vapor depositing process carried out in two different directions, and also to increase the birefringence quantity by utilizing a birefringence derived from a fine structure. This birefringence derived from the fine structure corresponds to a birefringence that is exerted by a shape anisotropy caused by concave and convex portions formed on the substrate of a dielectric material.

Upon producing the wavelength plate 4, periodic convex portions 44 and concave portions 45, each having a period of not more than the wavelength of light to be used, are formed on a substrate 41. Moreover, by stacking fine grains of a dielectric material on the convex portions 44 by oblique vapor depositing processes from two different directions, columnar portions 42 composed of fine grain layers 42a and 42b are formed thereon. Thus, interstices 43 are formed on the concave portions 45, that is, between the columnar portions 42. Then, an annealing treatment is carried out on a birefringent layer 46 composed of the columnar portions 42 and the interstices 43 under the aforementioned conditions so that moisture that exists inside of each interstice 43 is evaporated. Thereafter, by forming an inorganic compound on the birefringent layer 46 by a CVD method or the like at high density, a protective film 47 having a low moisture permeating property is formed thereon.

In this manner, by the use of the wavelength plate 4 in which the columnar portions 46 are formed on the convex portions 44 of the substrate 41 in a direction perpendicular to the substrate surface, with the interstices 43 being formed on the concave portions 45 of the substrate 41, it is possible to increase the birefringence quantity by utilizing a birefringence derived from the fine grains formed by the oblique vapor depositing processes from the two different directions, and it is also possible to further increase the birefringence quantity by utilizing a birefringence derived from the fine concave/convex shaped structure of the substrate 41. Moreover, by using a high refractive index-material containing Ta₂O₅ as its dielectric material, it is possible to obtain a wavelength plate that has a birefringence quantity of 0.13 or more in a visible light area and a superior wavelength dispersion property (wavelength dependence) having a difference in the birefringence quantities of two arbitrary wavelengths within the visible light area of 0.02 or less.

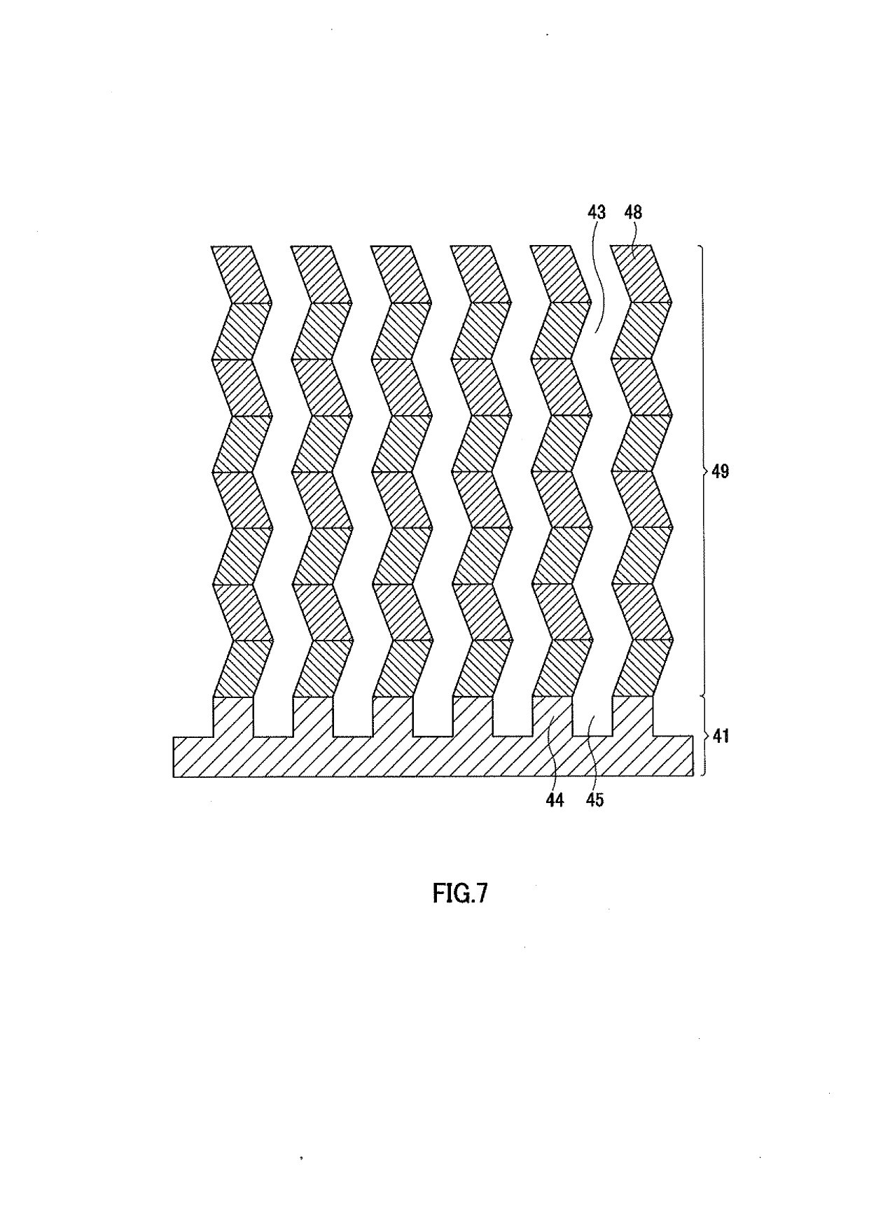

Additionally, in the examples of FIGS. 5 and 6, for convenience of explanation, a structure is exemplified in which the columnar portions composed of two fine grain layers are formed by carrying out one cycle of oblique vapor depositing processes for successively obliquely vapor depositing the dielectric material from two directions different from each other by 180°, however, not limited by this, the number of the fine grain layers may be set to several layers to several hundred layers. As the number of the fine grain layers is increased, the birefringence quantity of the wavelength plate can be further increased. For example, as shown in FIG. 7, by carrying out four cycles of oblique vapor depositing processes so as to successively vapor deposit the dielectric material from two directions different from each other by 180° on the convex portions 44 formed on the substrate 41, columnar portions 48 in which 8 fine grain layers are stacked on the convex portions 44 in a direction perpendicular to the substrate are formed, and a birefringent layer 49 composed of these columnar portion 48 and interstices 43 is formed. With this arrangement, it is possible to provide a wavelength plate that has an increased birefringence quantity in comparison with the wavelength plate having a smaller number of the fine grain layers.

In this manner, by combining the fine pattern and the birefringent layer (obliquely vapor deposited films) composed of a plurality of fine grain layers with each other, the birefringence quantity can be further increased, with the film thickness being reduced. In the wavelength plate produced in this manner also, by forming a protective film having a low moisture permeating property on the obliquely vapor deposited film, it is possible to realize a wavelength plate that exerts a high moisture resistant property with superior stability.

In particular, as the number of the fine grain layers is increased by successively vapor depositing a dielectric material from two directions different from each other by 180°, the structure of the interstices becomes complicate, with the result that it becomes further difficult to evaporate moisture adhering to the side faces of the columnar portions. The aforementioned annealing treatment is very effective as a method for evaporating moisture inside the interstices with such a complicated structure.

Additionally, on the substrate of the wavelength plate, an anti-reflection film (AR: Anti Reflection) may be formed on each of the two surfaces or one of the surfaces. In general, in the case of the wavelength plate formed by vapor depositing fine grains on a glass substrate by using an oblique vapor depositing process, the anti-reflection film is formed for the purpose of improving the transmittance. As the anti-reflection film, for example, a generally-used multilayer thin film composed of a high refraction index film and a low refraction index film may be used. By forming the anti-reflection film on the substrate, the surface reflection of the substrate can be reduced and the transmittance can be consequently increased. Additionally, in order to improve the transmittance, a structure in which a protective film compatibly serves as at least one portion of the anti-reflection film made of the multilayer thin film may be used.

For example, in the case when an SiO₂ (refractive index: 1.5) is formed as the protective film, this protective film is allowed to function as a low refractive index film in the multilayer film composed of the high refractive index film and the low refractive index film. Moreover, by forming an inorganic compound having a higher refractive index than this, such as TiO₂ (refractive index: 2.4) on the low refractive index film made of the SiO₂ protective film, the resulting film serves as a high refractive index film.

### 3. TREATMENT PROCESSES

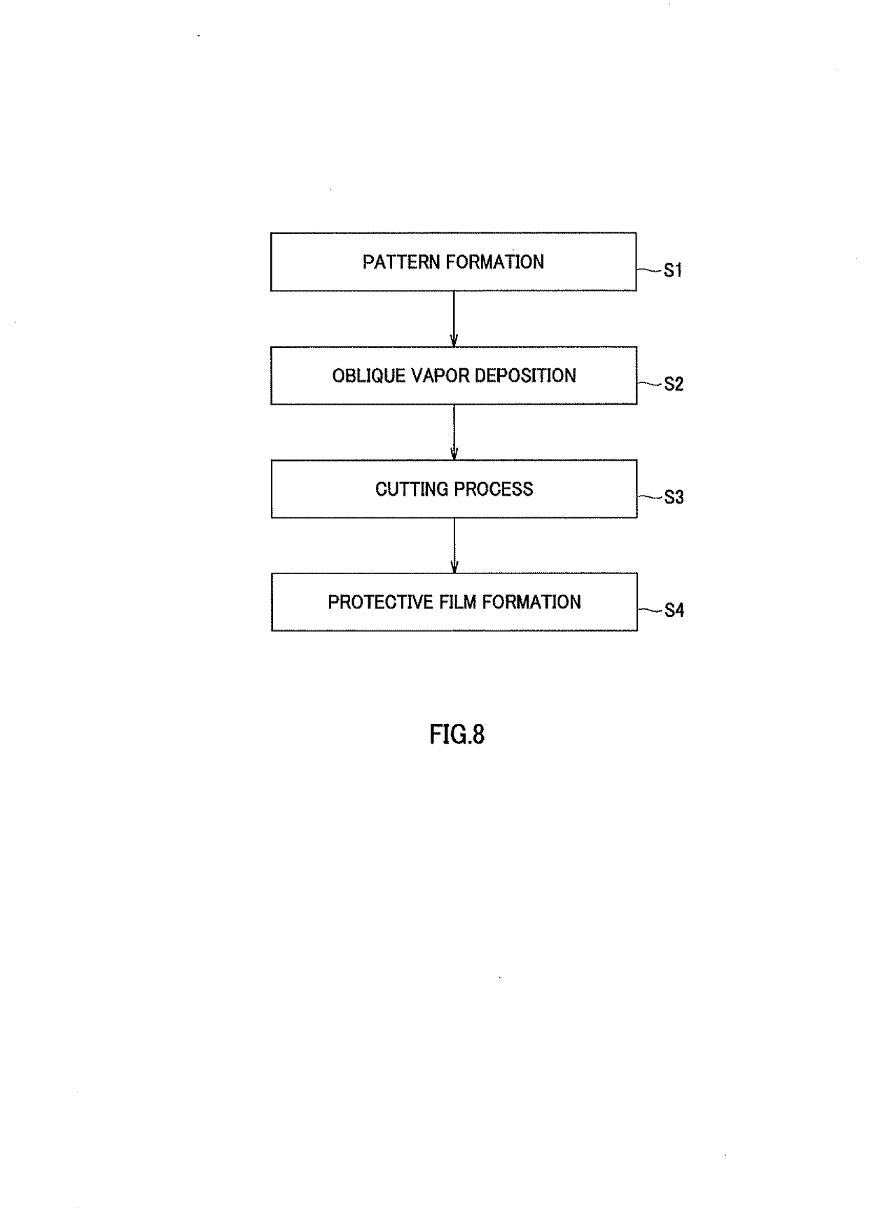

FIG. 8 is a flow chart that shows one example of treatment processes in a method for producing a wavelength plate in accordance with the present embodiment. First, in step S1, a fine pattern of periodic convex and concave portions, each having a period of not more than a wavelength to be used, is formed on a substrate. More specifically, supposing that an xy plane on x, y and z orthogonal coordinates is a substrate surface, a fine pattern composed of convex portions and concave portions that are formed thereon in the x-axis direction, with periods (pitches) each being not more than a wavelength of light to be used, that is, a one dimensional lattice (grid) that generates a path difference derived from the concave/convex structure, is formed.

In the forming method of the fine pattern, SiO₂ is deposited on a substrate by using a CVD method, and a photoresist pitch pattern is then formed by photolithography. Then, by a vacuum etching process using CF₄ as a reactive gas, a fine pattern of SiO₂ is formed. Additionally, in the case when a wavelength plate on which no fine pattern as shown in FIGS. 2 and 5 is formed, this step S1 is omitted.

Next, in step S2, a dielectric material is obliquely vapor deposited on the substrate with periodic convex portions and concave portions, each having a period of not more than a wavelength of light to be used, formed thereon, for example, with a vapor depositing angle in a range of 60° to 80°, so that a birefringent film is formed.

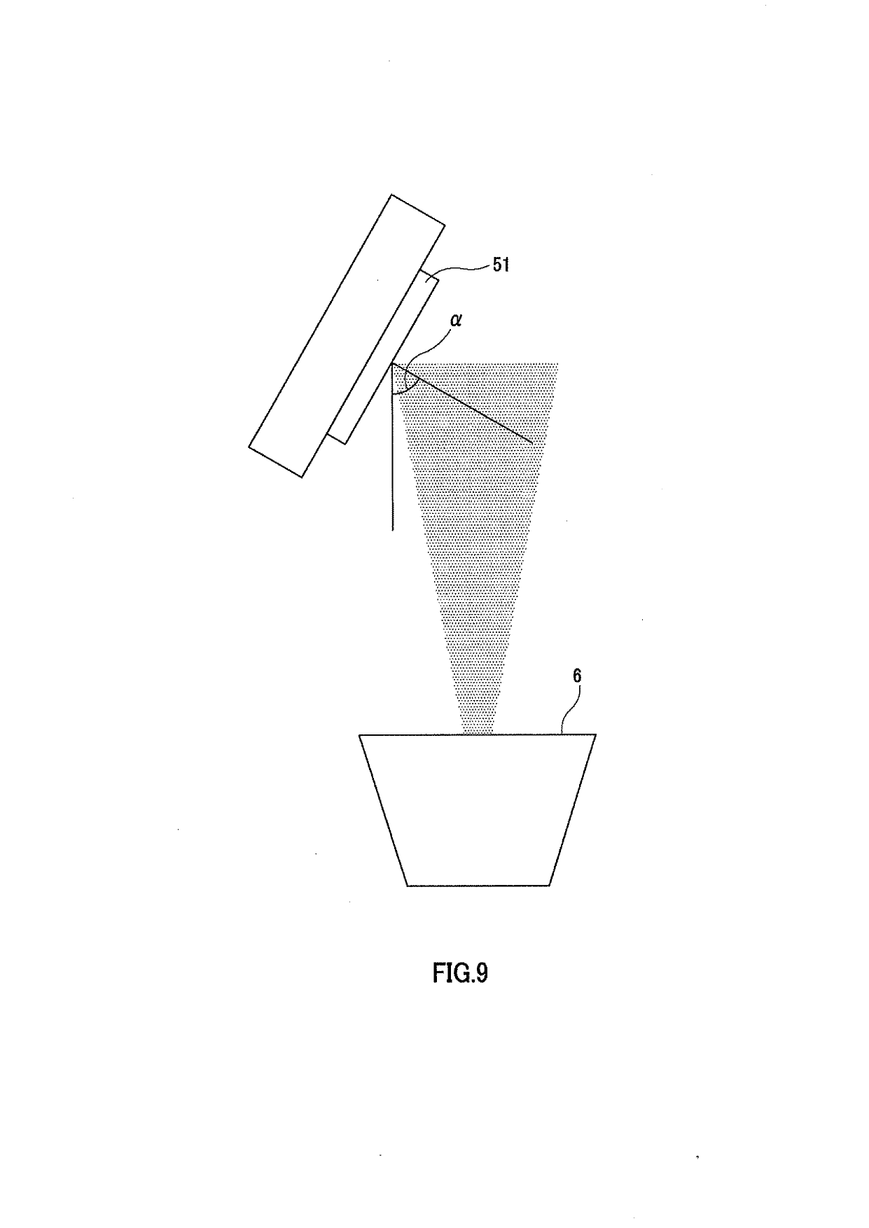

FIG. 9 is a view for explaining the outline of oblique vapor deposition. The oblique vapor deposition is carried out with a vapor deposition source 6 disposed in such a direction so as to have a vapor deposition angle α relative to the normal direction of a substrate surface 51, and by altering the vapor deposition angle α, the birefringence quantity of the film to be deposited is controlled. For example, in the case when a high refractive index material containing Ta₂O₅ is used as the dielectric material, by setting the vapor deposition angle α to 60° to 80°, the birefringence quantity can be increased.

Moreover, by vapor depositing the dielectric material in a direction perpendicular to lines of the periodic convex portions and concave portions on the substrate 51, that is, in a direction perpendicular to the lines of the one dimensional lattice, it becomes possible to increase the birefringence quantity.

Furthermore, upon vapor depositing a plurality of layers, supposing that an xy plane on x, y and z orthogonal coordinates is a substrate surface, by obliquely vapor depositing the dielectric material from two directions different from each other by 180° on the xy plane, the plural fine grain layers as shown in FIGS. 5 and 6 may be formed. For example, vapor depositing cycles in which, after having been obliquely vapor deposited in one of directions, the substrate is rotated by 180° so as to carry out an oblique vapor deposition in the other direction, are executed a plurality of times; thus, a multilayer film subjected to vapor depositing processes from two directions can be obtained.

Moreover, by carrying out vapor depositing cycles a plurality of times, with the thickness of each layer being set to 50 nm or less, more preferably, to 10 nm or less, it is possible to obtain a columnar shape extending in the z-axis direction so that the birefringence quantity can be increased.

In step S3, the substrate on which the birefringent films have been formed in step S2 is cut into a given size. In the cutting process, a cutting device, such as a glass scriber, is used.

In step S4, with respect to the substrate having the birefringent films formed thereon, cut in step S3, a protective film is formed on the birefringent films by a CVD method. Additionally, in step S4, onto the protective film formed on the birefringent films, an anti-reflection film may be further formed. In the case when the anti-reflection film is prepared as a multilayer thin film composed of a high refractive index film and a low refractive index film, the protective film formed on the birefringent films functions as one portion of the anti-reflection film, that is, as the high refractive index film or the low refractive index film.

For example, in the case when SiO₂ (refractive index: 1.5) is formed as the protective film, in the anti-reflection film composed of the high refractive index film and the low refractive index film, the protective film functions as the low refractive index film. In this case, in this step S4, an inorganic compound having a refractive index higher than that of SiO₂, such as TiO₂ (refractive index: 2.4) or the like, is formed on the low refractive index film made of the SiO₂ protective film.

In this manner, the birefringent films provided with columnar portions and interstices stacked in a columnar shape by oblique vapor depositing processes are formed, and after the birefringent films have been subjected to an annealing treatment at a temperature of 100° C. or more to 300° C. or less, a protective film, made of an organic compound formed with a high density, is further formed on the birefringent films; thus, it becomes possible to increase the birefringence quantity, and also to form a wavelength plate having a higher moisture resistant property and superior stability in comparison with the conventional plate.

Since the wavelength plate of the present embodiment, produced as described above, is capable of dealing with high light density, when used for optical apparatuses, such as a liquid crystal projector, etc., it becomes possible to miniaturize the optical units.

Although the present invention has been described above concretely by way of embodiments thereof, it is needless to say that the invention is not limited to the above embodiments, but that various changes may be made within the scope not departing from the gist of the invention.

### Examples

### 4. EXAMPLES

The following description will discuss specific examples of the present invention. However, the scope of the present invention is not intended to be limited by the following examples.

### Example 1

On a glass substrate was vapor deposited Ta₂O₅ serving as a dielectric material so as to allow a vapor depositing source to make an angle of 70° relative to the normal direction to the surface of the glass substrate so that columnar portions were formed. Next, the resulting substrate was subjected to an annealing treatment at a temperature of 200° C. so that moisture adhering to gaps (interstices) between the columnar portions was evaporated. On a birefringent film composed of the columnar portions and interstices formed on the glass substrate was formed SiO₂ as a protective film by a CVD method so that a sample of a wavelength plate of example 1 was produced.

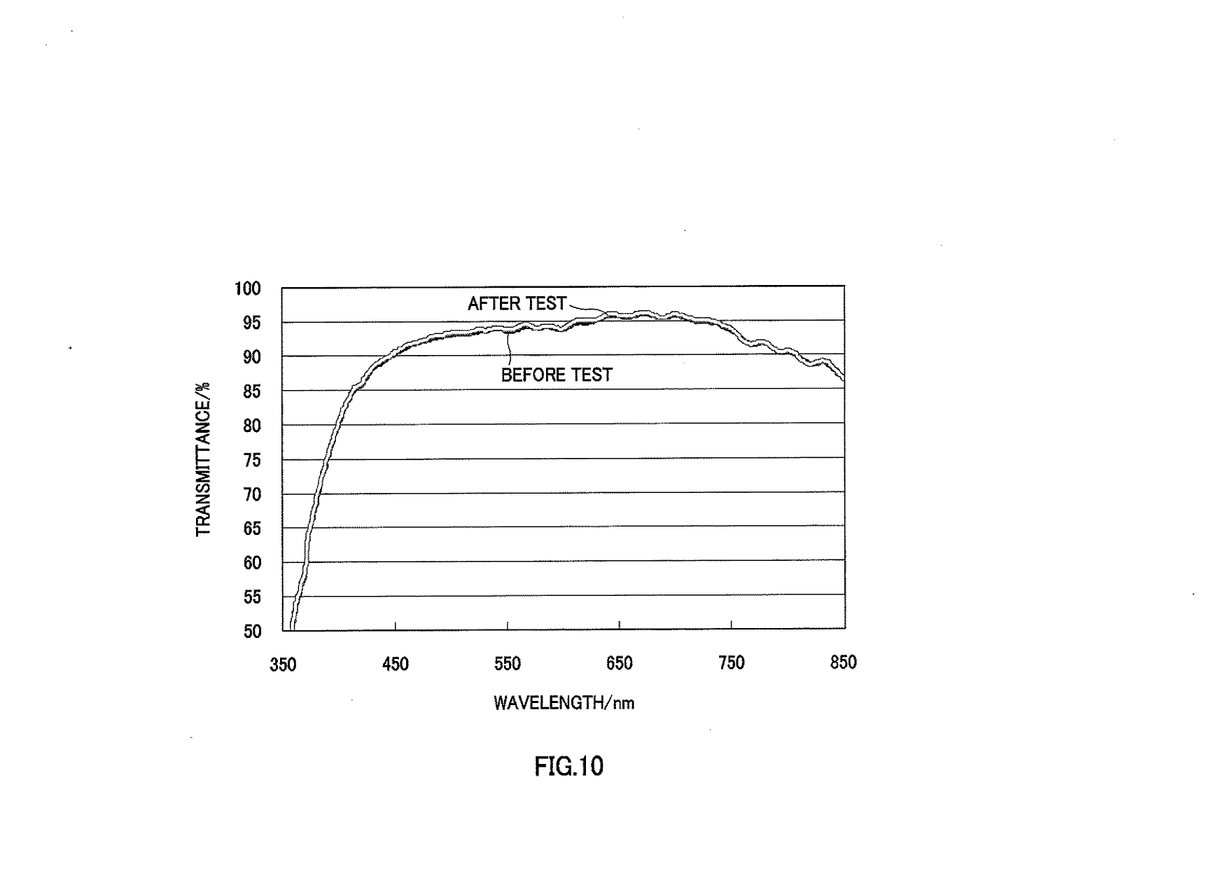

In order to examine the safety of the sample of the wavelength plate thus formed, it was held in environments of a temperature of 60° C. and a humidity of 90% for 100 hours (h) as a moisture resistant load test. FIG. 10 shows a transmittance (curve (A)) immediately after the completion of the sample and a transmittance (curve (B)) obtained after having been held for 100 hours in the moisture resistant load test with respect to the sample of the wavelength plate in example 1. As shown in FIG. 10, in the sample of the wavelength plate of example 1, no difference was caused in the transmittances between that obtained immediately after the completion of the sample and that obtained after having been held for 100 hours in the moisture resistant load test.

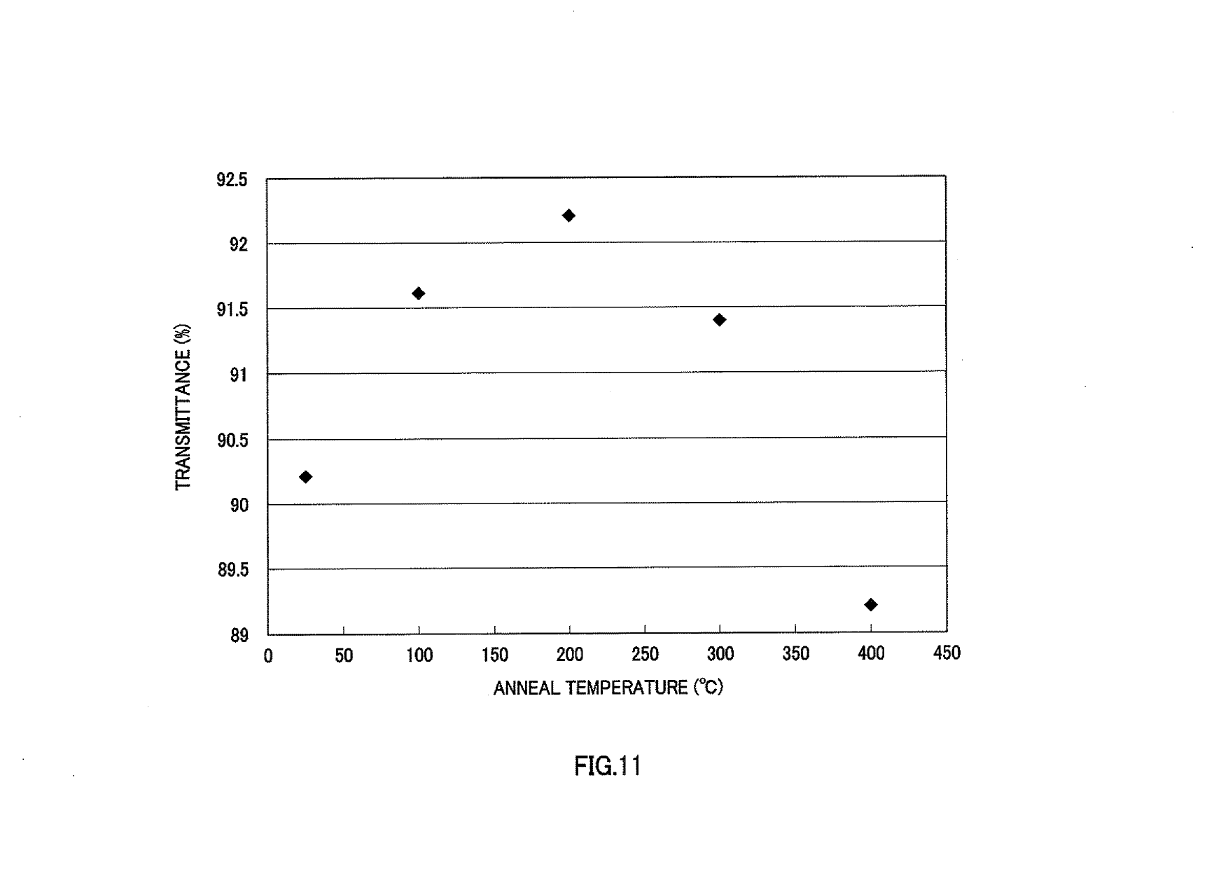

FIG. 11 is a view that shows a transmittance at a wavelength of 550 nm in each of samples of wavelength plates that were produced in the same manner as in example 1, except that the sample of the wavelength plate of example 1 was changed, with the annealing temperature being changed to 25° C., 100° C., 300° C. and 400° C. respectively. In general, from the viewpoint of characteristics of the wavelength plate, a transmittance of 90% or more is required, and as shown in FIG. 11, the sample of the wavelength plate of example 1 could achieve the highest transmittance (92% or more) among these samples.

In example 1, after carrying out an annealing treatment at 200° C. thereon, by forming a protective film having a low moisture permeating property with SiO₂ formed therein at high density by a CVD method, the wavelength plate thus produced had a high moisture resistant property, and was superior in durability and stability.

### Comparative Example 1

The same processes as those of example 1 were carried out except that SiO₂ was formed as a protective film on the birefringent layer composed of columnar portions and interstices formed on a glass substrate by using a resistor heating vapor deposition method so that a sample of a wavelength plate was produced. More specifically, by supplying SiO₂ to a heated resistor member so as to be heated and evaporated, a protective film is formed by allowing evaporated SiO₂ particles to adhere to the surface of the birefringent layer on the substrate so that a sample of a wavelength plate of comparative example 1 was produced.

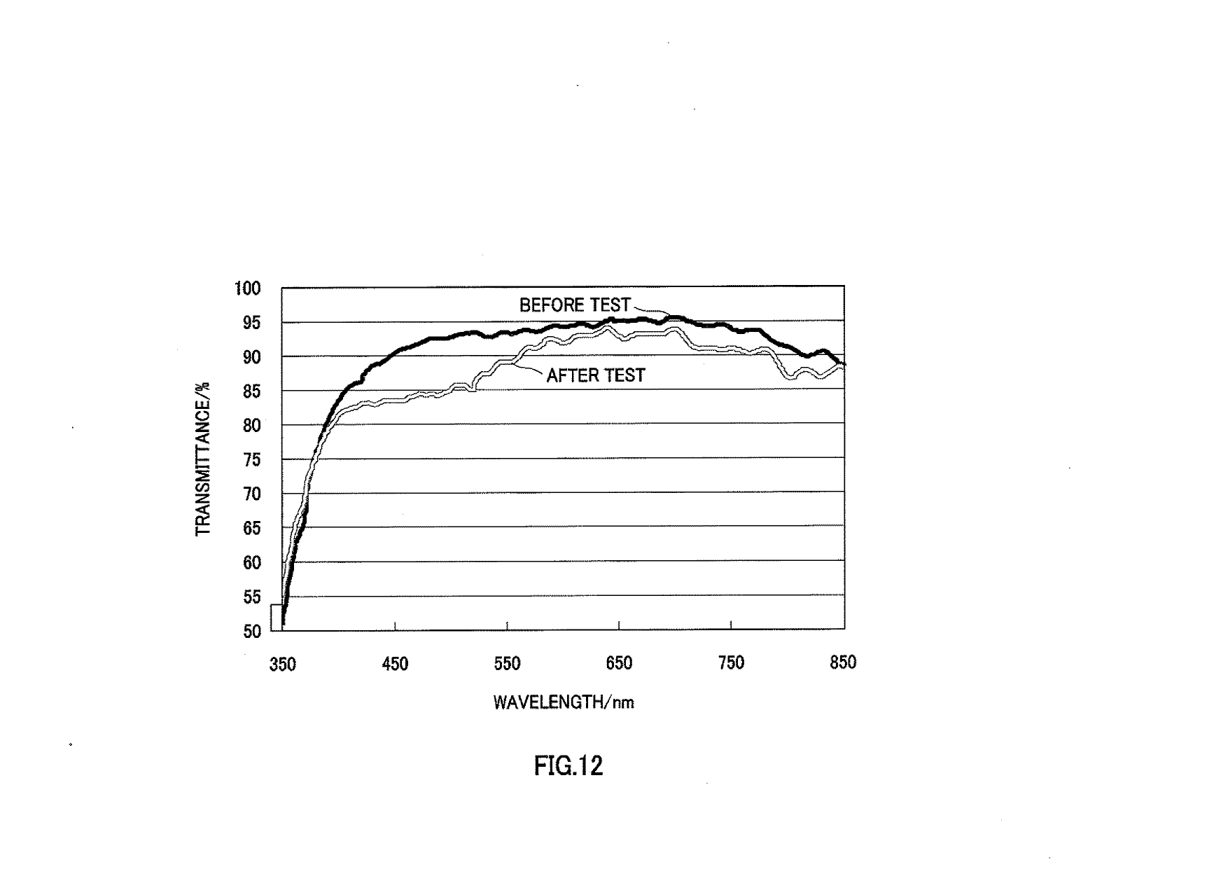

By using the sample of a wavelength plate of comparative example 1, the same moisture resistant load test as that of example 1 (held in environments of a temperature of 60° C. and a humidity of 90% for 100 hours (h)) was carried out. FIG. 12 shows a transmittance (curve (A)) immediately after the completion of the sample and a transmittance (curve (B)) obtained after having been held for 100 hours in the moisture resistant load test with respect to the sample of the wavelength plate in comparative example 1. As shown in FIG. 12, in the sample of the wavelength plate of comparative example 1, the transmittance after the moisture resistant load test was reduced in comparison with that immediately after the completion of the sample in a range of a wavelength from 400 nm or more to 850 nm or less.

In comparative example 1, since the protective film was formed by using the resistor heating vapor deposition method, SiO₂ was not formed at high density, failing to allow the protective film to have a low moisture permeating property. Consequently, the produced wavelength plate had a low moisture resistant property with inferior durability and safety.

### Comparative Example 2

The same processes as those of example 1 were carried out except that no protective film was formed on the birefringent film made of columnar portions and interstices formed on a glass substrate so that a sample of a wavelength plate was produced.

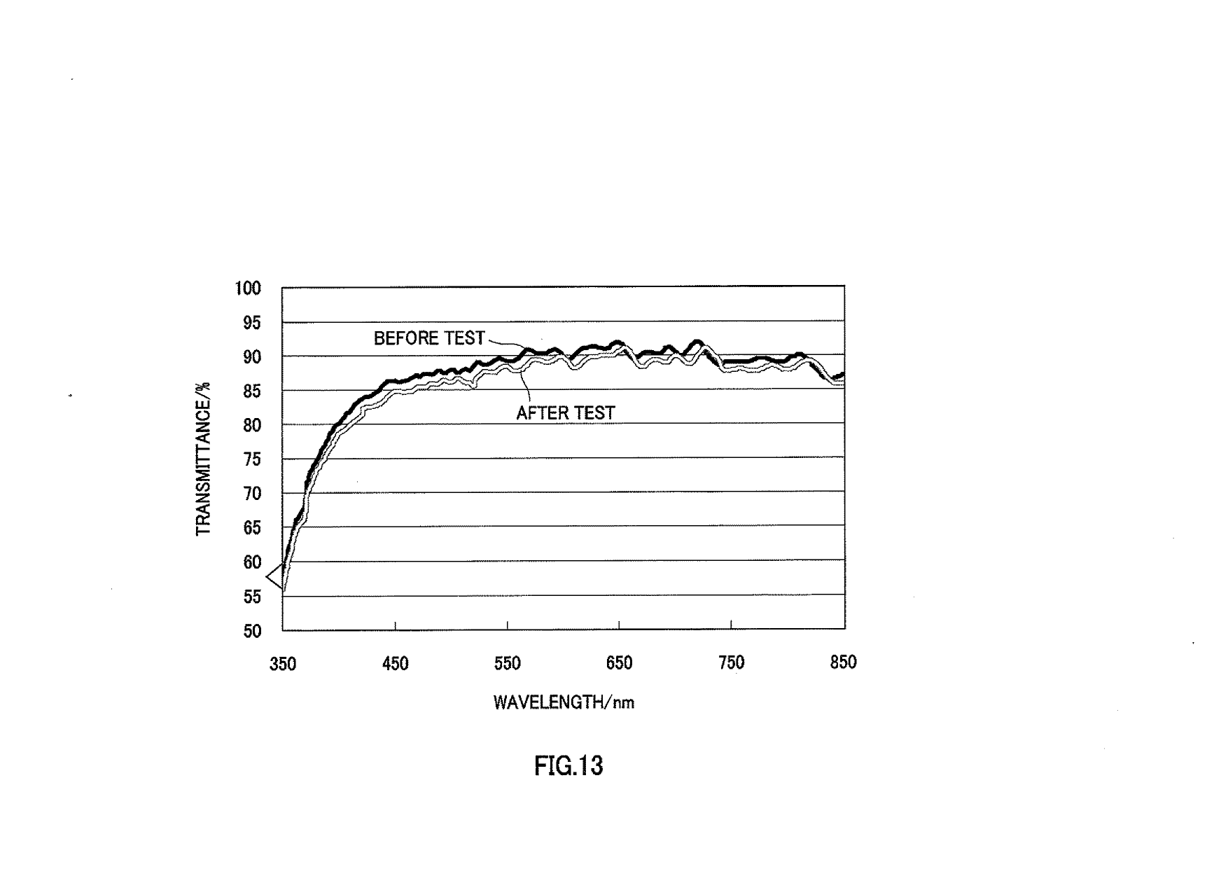

The same moisture resistant load tests (held in environments of a temperature of 60° C. and a humidity of 90% for 100 hours (h)) as those of example 1 were carried out. FIG. 13 shows a transmittance (curve (A)) immediately after the completion of the sample and a transmittance (curve (B)) obtained after having been held for 100 hours in the moisture resistant load test with respect to the sample of the wavelength plate in comparative example 2. As shown in FIG. 13, in the sample of the wavelength plate of comparative example 2, the transmittance after the moisture resistant load test was reduced in comparison with that immediately after the completion of the sample in almost all ranges of a wavelength from 350 nm or more to 850 nm or less. Moreover, in the sample of the wavelength plate of comparative example 2, cracks occurred in the fine grains of the columnar portions.

In comparative example 2, since no protective film was formed, the produced wavelength plate had a low moisture resistant property with inferior durability and safety.

### Applied Example 1

A wavelength plate was produced in which a fine pattern was formed on a glass substrate on which a one dimensional lattice having a pitch of 150 nm and a depth of 50 nm was formed. Then, effects of this fine pattern were evaluated. By obliquely vapor depositing Ta₂O₅ serving as a dielectric material in a direction perpendicular to the lines of a one dimensional lattice, with a vapor deposition angle of 70° relative to the normal direction to the surface of the glass substrate so that a birefringent film of one layer was formed. The film thickness of the birefringent film was set to 1.2 μm. Moreover, in the same manner as described above, by using a flat substrate with no pattern formed thereon, a birefringent film was formed on this flat substrate.

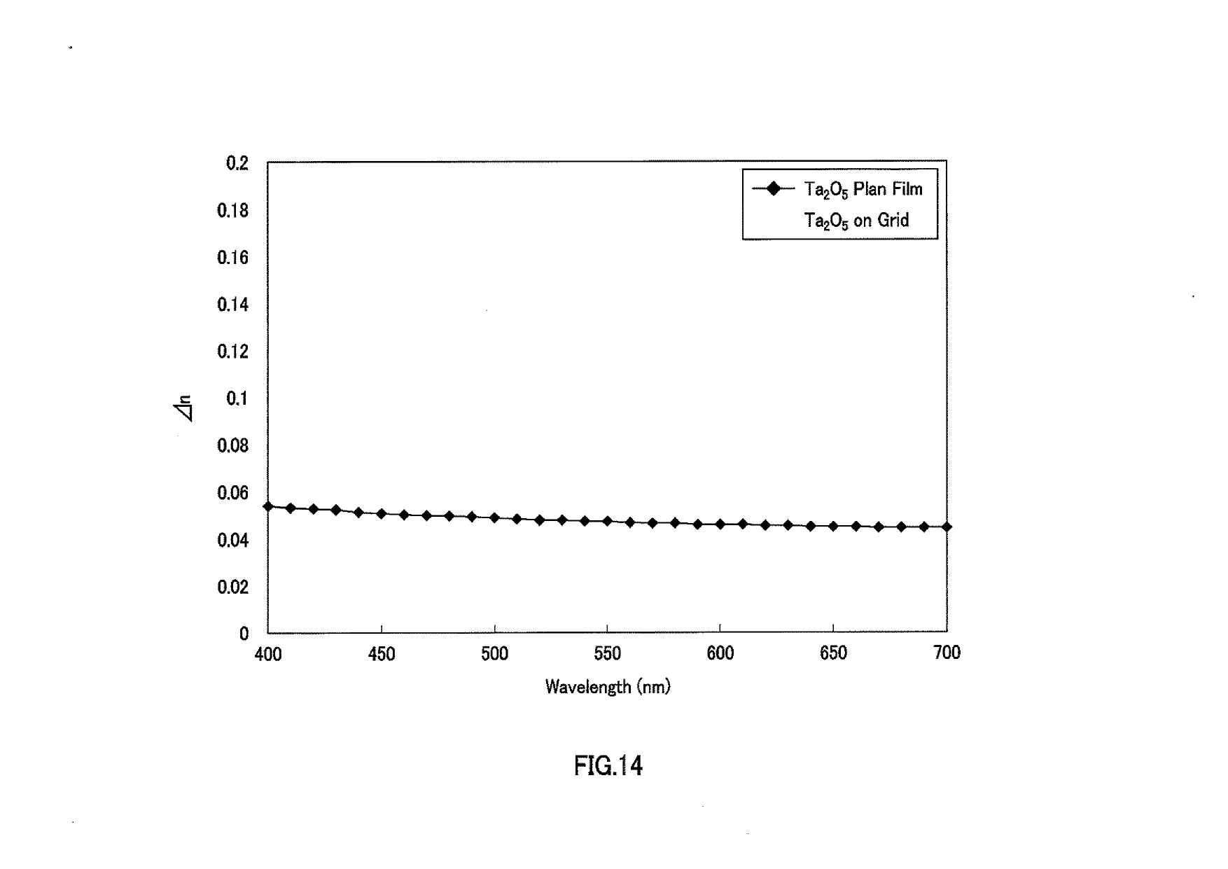

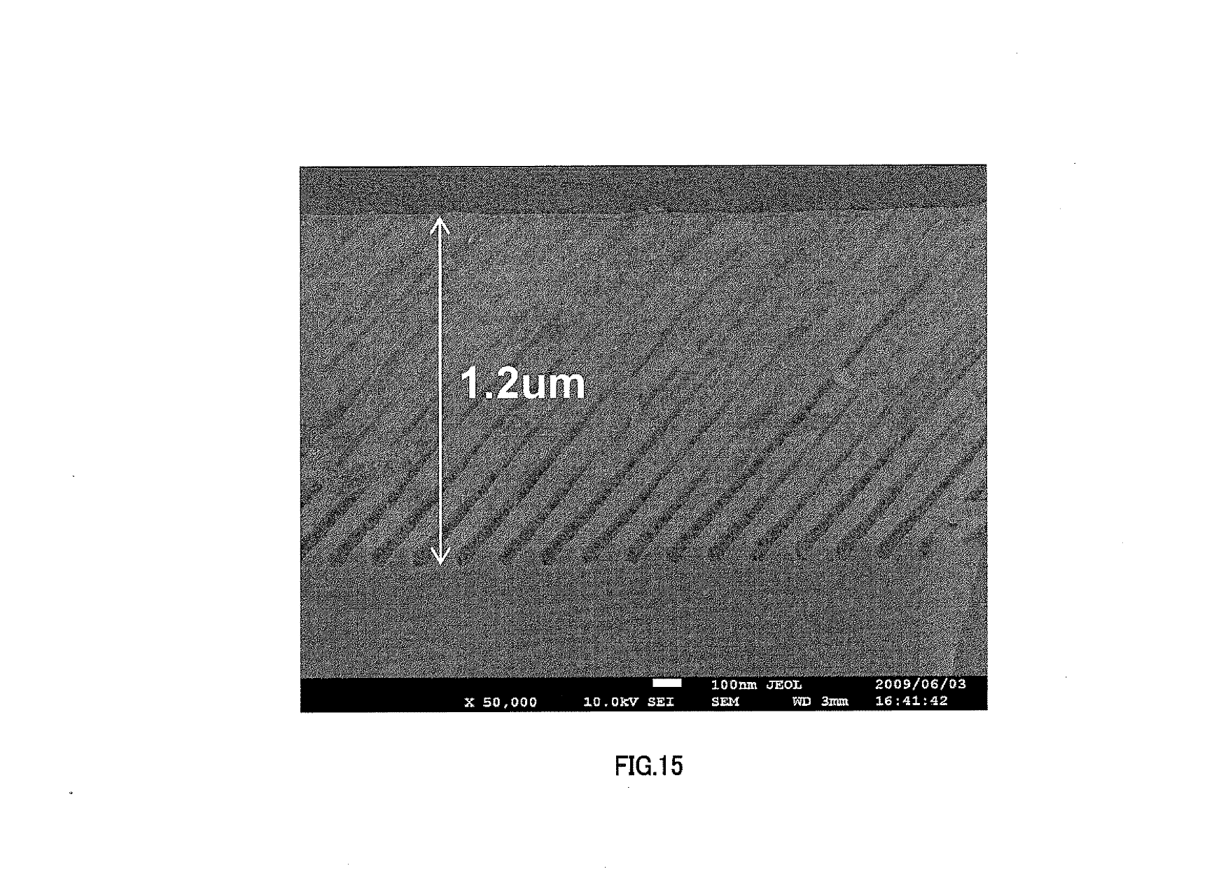

FIG. 14 is a graph indicating comparisons of the birefringence quantities between the wavelength plate using the one dimensional lattice substrate and the wavelength plate using the flat plate. Moreover, FIG. 15 shows an SEM (Scanning Electron Microscope) image of a cross section of the wavelength plate using the one dimensional lattice substrate.

The wavelength plate using the one dimensional lattice substrate had a birefringence quantity of 2.8 times higher than that derived from the vapor deposition process using the conventional flat plate. It is considered that by forming a film on the one dimensional lattice substrate, this effect was obtained by an additional effect of a structural birefringence derived from interstices formed between the lattices.

In this manner, in accordance with the wavelength plate using a one dimensional lattice substrate as described above, a desired phase characteristic can be obtained even by using a thinner film in comparison with the conventional film. Moreover, the thinness of the film provides various advantages, such as high speed and highly efficient production processes, reduced costs for materials to be used for the film formation, etc.

### REFERENCE SIGNS LIST

1 . . . wavelength plate, 11 . . . substrate, 12 . . . columnar portion, 13 . . . interstice, 14 . . . birefringent film, 15 . . . protective film

1. A method of producing a wavelength plate comprising the steps of:
obliquely vapor depositing a dielectric material on a substrate to form a birefringent layer having columnar portions formed by stacking fine grains of the dielectric material in a columnar shape and interstices formed between the columnar portions;
annealing the birefringent layer at a temperature in a range from 100° C. or more to 300° C. or less; and
by forming an inorganic compound at high density on the birefringent layer that has been subjected to the annealing treatment, forming a protective film thereon.

2. The method of producing a wavelength plate according to claim 1, wherein in the protective film forming step, the protective film is formed on the birefringent film by using at least one method selected from the group consisting of a chemical vapor deposition method, a plasma assist method and a sputtering method.

3. The method of producing a wavelength plate according to claim 1, further comprising the step of:
forming a high refractive index film having a higher refractive index than that of the protective film on the protective film,
wherein an anti-reflection film composed of the protective film and the high refractive index film is formed.

4. The method of producing a wavelength plate according to claim 1, wherein the inorganic compound is SiO₂.

5. The method of producing a wavelength plate according to claim 1, wherein the dielectric material is Ta₂O₅.

6. The method of producing a wavelength plate according to claim 1, wherein on the substrate, periodic concave portions and convex portions, each having a period of not more than a wavelength of light to be used, are formed, and in the birefringent layer forming step, the dielectric material is obliquely vapor deposited on the convex portions.

7. The method of producing a wavelength plate according to claim 1, wherein in the birefringent layer forming step, at least two or more of the birefringent layers are stacked with the stacking direction being successively inverted by 180°.
